(19) United States
(12) Patent Application Publication
(10) Pub. No.: US 2012/0074430 A1
(43) Pub. Date: Mar. 29, 2012

(54) Radiating substrate and method for manufacturing the radiating substrate, and luminous element package with the radiating substrate

(75) Inventors: Kyu Sang Lee, Suwon-si (KR); Sang Su Hong, Suwon-si (KR); Hyun Ho Lim, Suwon-si (KR); Hwa Young Lee, Suwon-si (KR); Choon Keun Lee, Suwon-si (KR); Jae Choon Cho, Suwon-si (KR)

(73) Assignee: SAMSUNG ELECTRO-MECHANICS CO., LTD., Suwon (KR)

(21) Appl. No.: 13/137,877

(22) Filed: Sep. 20, 2011

(30) Foreign Application Priority Data
Sep. 29, 2010 (KR) 10-2010-0094414

(51) Int. Cl. H01L 33/64; B32B 27/20; B32B 37/24; C08L 63/00; B32B 27/38; B32B 9/00; B82Y 30/00

(52) U.S. Cl. 257/79; 428/408; 428/688; 156/242; 523/468; 257/E33.075; 977/734

(57) ABSTRACT

Disclosed herein is a radiating substrate radiating heat generated from a predetermined heating element to the outside. The radiating substrate includes polymer resins and graphenes distributed in the polymer resins.

### CROSS REFERENCE TO RELATED APPLICATION

This application claims the benefit of Korean Patent Application No. 10-2010-0094414, filed on Sep. 29, 2010, entitled “Radiating Substrate and Method For Manufacturing the Radiating Substrate, and Luminous Element Package With the Radiating Substrate”, which is hereby incorporated by reference in its entirety into this application.

### BACKGROUND OF THE INVENTION

1. Technical Field

The present invention relates to a radiating substrate and a method for manufacturing the radiating substrate, and a luminous element package with the radiating substrate.

2. Description of the Related Art

In general, a luminous element package is formed by packaging a luminous element such as a light emitting diode (LED), a light emitting laser, and the like, in order to be equipped in home appliances, remote controllers, electrical signboards, displays, automatic devices, illumination devices, and the like. Recently, as the luminous element is applied to various fields, a package technology for effectively treating heat generated from the luminous element is required. Particularly, in the case of a high-output light emitting diode applied to the illumination device, power consumption increases to generate a high-temperature heat. Therefore, it is required to improve radiating efficiency of the luminous element.

### SUMMARY OF THE INVENTION

An object of the present invention is to provide a radiating substrate having improved radiating efficiency and a luminous element package with the radiating substrate.

Another object of the present invention is to provide a method for manufacturing a radiating substrate having improved radiating efficiency.

According to an exemplary embodiment of the present invention, there is provided a radiating substrate radiating heat generated from a heating element to the outside, including: polymer resins; and graphenes distributed in the polymer resins to radiate the heat generated from the heating element to the outside.

The graphenes having a single-layer sheet structure may be interposed between the polymer resins.

The radiating substrate may further include a derivative formed on a surface of the graphene so as to increase reactivity between the graphene and a polar solvent.

Epoxy resin may be used as the polymer resin.

The radiating substrate may have a multi-layer structure in which a plurality of insulating films are stacked.

According to another exemplary embodiment of the present invention, there is provided a method for manufacturing a radiating substrate bonded to a heating element to radiate heat generated from the heating element to the outside, including; preparing a mixture by mixing polymer resins and graphenes; forming a polymer paste by mixing and dispersing the mixture; forming a plurality of insulating films by casting the polymer paste; and forming a substrate laminate by stacking and firing the insulating films.

The preparing the mixture may include adjusting an added amount of the graphene so that the graphene is 0.05 to 40 wt % for a total weight percent of the polymer paste.

Epoxy resin may be used as the polymer resin.

The preparing the mixture may include forming a derivative on a surface of the graphene.

According to another exemplary embodiment of the present invention, there is provided a luminous element package, including: a luminous element; and a radiating substrate bonded to the luminous element to radiate heat generated from the luminous element; wherein the radiating substrate includes: polymer resins; and graphenes distributed in the polymer resins to radiate the heat generated from the luminous element to the outside.

The graphenes having a single-layer sheet structure may be interposed between the polymer resins.

The radiating substrate may have a multi-layer structure in which a plurality of insulating films are stacked.

### BRIEF DESCRIPTION OF THE DRAWINGS

FIG. 1 is a diagram showing a luminous element package according to an exemplary embodiment of the present invention;

FIG. 2 is an enlarged diagram of an inner area of a buildup insulating film shown in FIG. 1; and

FIG. 3 is a diagram for comparing and explaining a luminous element package according to an exemplary embodiment of the present invention with a general radiating element package in terms of radiating effect.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. Rather, these embodiments may be provided so that this disclosure will be thorough and complete, and will fully convey the scope of the invention to those skilled in the art. Like reference numerals in the drawings denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

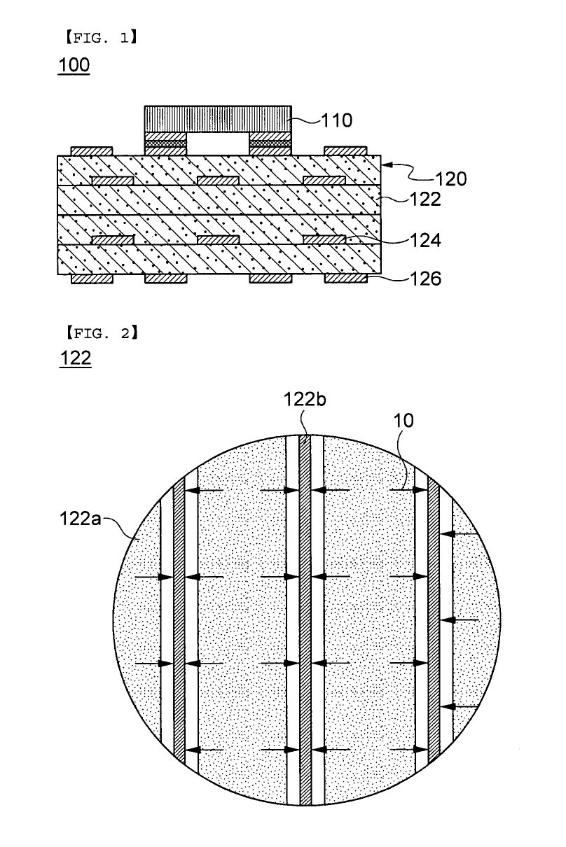

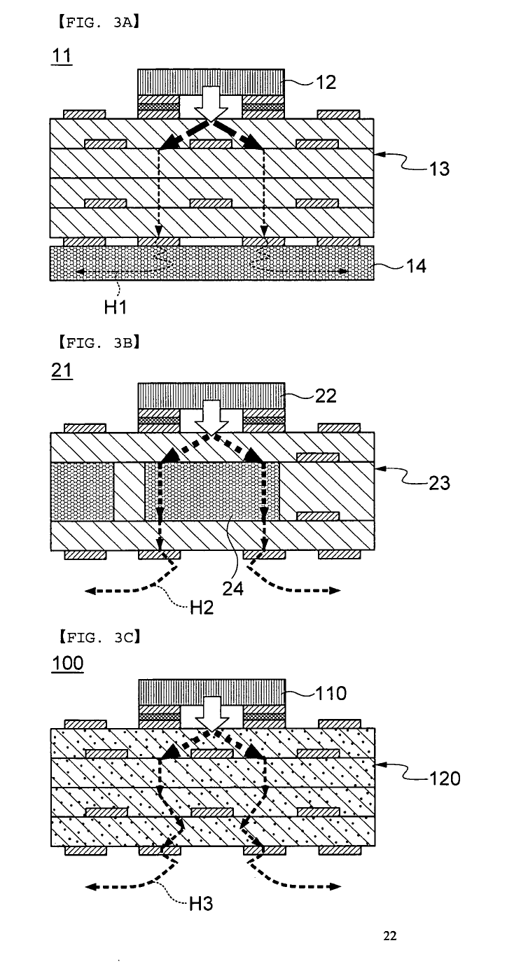

FIG. 1 is a diagram showing a luminous element package according to an exemplary embodiment of the present invention, and FIG. 2 is an enlarged diagram of an inner area of a buildup insulating film shown in FIG. 1.

Referring to FIGS. 1 and 2, a luminous element package 100 according to an exemplary embodiment of the present invention may include a luminous element 110 and a radiating substrate 120 bonded to each other.

The luminous element 110 may be at least any one of a light emitting diode and a laser diode. As an example, the luminous element 110 may be the light emitting diode. A connecting means (not shown), such as a lead frame, for electrically connecting the luminous element 110 to the radiating substrate 120 may be provided on one surface of the luminous element 110 which is opposite to the radiating substrate 120. In order to protect the luminous element 110 from an external environment, the luminous element package 100 may further include a molding film (not shown) covering and sealing the luminous element 110.

The radiating substrate 120 may radiate heat generated from the luminous element 110 to the outside. In addition, the radiating substrate 120 may be a package structure provided in order to mount the luminous element 110 on an external electronic device (not shown).

The radiating substrate 120 may have a substrate structure in which a plurality of insulating films are stacked. For example, the radiating substrate 120 may have a buildup multi-layer circuit substrate structure. Accordingly, the radiating substrate 120 may have a structure in which a plurality of buildup insulating films 122 are stacked. Each of the insulating films 122 may include an inner layer circuit pattern 124. An outer circuit pattern 126 electrically connected to the inner layer circuit pattern 124 may be provided on the outside of the radiating substrate 120. Accordingly, the luminous element 110 may be bonded to the outer layer circuit pattern 126 to be electrically connected to the inner layer circuit pattern 124.

Meanwhile, the radiating substrate 120 may have composition with very high thermal conductivity in order to effectively radiate the heat generated from the luminous element 110. For example, as shown in FIG. 2, the insulating films 122 may include polymer resins 122a and graphenes 122b.

The polymer resin 122a may include epoxy resin. The epoxy resin may be an insulating material used as an interlayer insulating material of the radiating substrate 120 in manufacturing the buildup multi-layer circuit substrate. To this end, epoxy resin having excellent heat resistance, chemical resistance and electrical characteristics is preferably used. For example, the epoxy resin may include at least any one heterocyclic epoxy resin of bisphenol A type epoxy resin, bisphenol F type epoxy resin, phenol novolac type epoxy resin, dicyclopentadiene type epoxy resin, and triglycidyl isocyanate. Alternatively, the epoxy resin may include bromine substituted epoxy resin.

The graphene 122b may be disposed between the polymer resins 122a to effectively receive the heat generated from the luminous element 110, thereby radiating the heat from the radiating substrate 120 to the outside. The graphene 122b may have high thermal conductivity. For example, it is known that the graphene 122b generally has thermal conductivity twice higher than that of diamond. Accordingly, the radiating substrate 120 containing the graphene 122b may effectively radiate the heat generated from the luminous element 110.

In addition, the graphene 122b, which is carbon nano material, may serve as a bridge between the polymer resins 122a within the polymer resin composition. For example, the graphene 122b may have rich electron cloud density, thereby making it possible to link the polymer resins 122a with strong attraction. At this time, the attraction for the polymer resin 122a provided by the graphene 122b may be much stronger than Van Der Waals force of general epoxy resin. Accordingly, the insulating films 122 of the radiating substrate 120 may have very low expansion and contraction ratio according to temperature change, due to the graphene 122b.

Herein, about 0.05 to 40 wt % of the graphene 122b may be added for a total weight percent of the composition for manufacturing the insulating film 122. In the case in which the content of the graphene 122b is lower than 0.05 wt %, the content of the graphene 122b is relatively very low, such that it is difficult to expect radiating efficiency of the radiating substrate 120 and effect of the graphene linking the polymer resins 122a with the strong attraction, and the like. On the other hand, in the case in which the content of the graphene 122b is over 40 wt %, insulating characteristics of the radiating substrate 120 may be deteriorated due to excessive addition of the graphene 122b, and characteristics of the material may be deteriorated due to relative reduction of other materials.

In addition, the insulating film 122 may further include a curing agent, a curing accelerator, and other various additives. The detailed description thereof will be described below.

Meanwhile, the radiating substrate 120 as set forth above may be manufactured through the following processes. First, a polymer resin 122a and a graphene 122b may be mixed with a predetermined solvent to manufacture a mixture. Herein, since the graphene 122b has very high polarity, it may not be easily dissolved in the solvent. Accordingly, a derivative such as a carboxyl group, an alkyl group, an amine group, and the like is formed on a surface of the graphene 122b, thereby making it possible to raise solubility of the graphene 122b with regard to the solvent.

In addition, during the process manufacturing the mixture, curing agent, curing accelerator, and other various additives may be further added, in addition to the polymer resin 122a and the graphene 122b.

As the polymer resin 122a, epoxy resin may be used. For example, the epoxy resin may include at least any one heterocyclic epoxy resin of bisphenol A type epoxy resin, bisphenol F type epoxy resin, phenol novolac type epoxy resin, dicyclopentadiene type epoxy resin, and triglycidyl isocyanate. Alternatively, as the epoxy resin, at least any one of bromine substituted epoxy resins may be used.

As the curing agent, at least any one of amines, imidazols, guanines, acid anhydrides, dicyandiamides, and polyamines may be used. Alternatively, as the curing agent, at least any one of 2-methylimidazole, 2-phenylimidazole, 2-phenyl-4-phenylimidazole, bis(2-ethyl-4-methyllimidazole), 2-phenyl-4-methyl-5-hydroxymethyl hydroxyl, triazine added imidazole, 2-phenyl-4,5-dihydpoxymethylimidazole, phthalic acid anhydride, tetrahydro phthalic acid anhydride, methylbutenyltetra hydro phthalic acid anhydride, hexa hydro phthalic acid anhydride, methylhydro phthalic acid anhydride, trimellitic acid anhydride, pyromellitic acid anhydride, and benzophenonetetra carboxylic acid anhydride may be used.

As the curing accelerator, at least any one of phenol, cyanate ester, amine, and imidazole may be used.

The graphene 122b, which is a carbon nano material, may serve as a bridge between the epoxy resins within the polymer resin 122a composition. For example, the graphene 122b may have rich electron cloud density, thereby making it possible to link the epoxy resins with strong attraction. At this time, the attraction for the epoxy resin provided by the graphene may be much stronger than Van Der Waals force of the epoxy resin. Accordingly, the polymer resin composition may have very low expansion and contraction ratio according to temperature change, due to the graphene.

About 0.05 to 40 wt % of the graphene may be added for the total weight percent of the polymer resin composition. In the case in which the content of the graphene is lower than 0.05 wt %, the content of the graphene is relatively too low, such that it is difficult to expect effect of the graphene linking the epoxy resins with strong attraction. On the other hand, in the case in which the content of the graphene is over 40 wt %, insulating characteristics of the polymer resin composition may be deteriorated due to excessive addition of the graphene, and characteristics of the material may be deteriorated due to relative reduction of other materials.

In the case of manufacturing the insulating film using the polymer resin composition and further manufacturing a multi-layer circuit substrate using the insulating film, the additives may be provided in order to improve manufacturing characteristics and substrate characteristics. For example, the additives may include filler, reactive diluent, binder, and the like.

As the filler, inorganic filler or organic filler may be used. As the filler, for example, at least any one of barium sulfate, barium titanate, silicon oxide powder, amorphous silica, talc, clay, and mica powder may be used. The added amount of the filler may be adjusted to about 1 wt % to 30 wt % based on a total weight percent of the polymer resin composition. When the added amount of the filler is below 1 wt %, it may be difficult to function as the filler. On the other hand, when the added amount of the filler is over 30 wt %, electrical characteristics such as dielectric constants of products made of the polymer resin composition may be deteriorated.

The reactive diluent may be a material for adjusting viscosity in manufacturing the polymer resin composition to facilitate manufacturing workability. As the reactive diluent, at least any one of phenyl glycidyl ether, resorcinol diglycidyl ether, ethylene glycol diglycidyl ether, clycerol triglycidyl ether, resol novolac type phenol resin, and isothiocyanate compound may be used.

The binder may be provided in order to improve flexibility of the insulating film made of the polymer resin composition and to improve material characteristics. As the binder, at least any one of polyacryl resin, polyamide resin, polyamideimide resin, polycyanate resin, and polyester resin may be used.

30 wt % or less of the reactive diluent and the binder may be added for the total weight percent of the polymer resin composition. If the content of the reactive diluent and binder is over 30 wt % for the total weight percent of the polymer resin composition, material characteristics of the polymer resin composition are rather deteriorated, such that electrical, mechanical and chemical characteristics of the products made of the polymer resin composition may be deteriorated.

In addition, the polymer resin composition may further include a predetermined rubber as the additive. For example, the insulating film laminated on an inner layer circuit is procured and then subjected to a wet roughening process using an oxidizing agent in order to improve an adhesion with a plating layer. Accordingly, rubber, epoxy modified rubber resin, or the like, soluble in the oxidizing agent may be used in an insulating film composition as roughening component (rubber). An example of rubber used may include at least any one of poly butadiene rubber, modified epoxy, modified acrylonitryl, urethane modified poly butadiene rubber, acrylonitryl butadiene rubber, acryl rubber dispersion type epoxy resin, without being limited thereto. The added amount of the roughening component may be adjusted to be about 5 to 30 wt % for the total weight percent of the polymer resin composition. If the roughening component is below 5 wt %, roughening performance may be lowered. On the other hand, when the roughening component is over 30 wt %, mechanical strength of a product made of the polymer resin composition may be deteriorated.

After mixing and dispersing the polymer resin composition for manufacturing the radiating substrate manufactured through the method as described above, the polymer resin composition is cast, thereby being manufactured in a film form. The mixing and dispersion of the polymer resin composition may be performed using a 3-ball mill roller. The insulating films manufactured in the scheme as described above are stacked and fired, thereby making it possible to form a buildup multi-layer circuit substrate. During the process, a step of forming metal circuit patterns on each of the insulating films may be added. Accordingly, the radiating substrate 120 having a plurality of insulating films 122 stacked therein and having the inner layer circuit pattern 124 and the outer layer circuit pattern 126 may be manufactured.

Hereinafter, the luminous element package 100 according to an exemplary embodiment of the present invention will be compared with a general radiating element package and described in terms of radiating effect.

FIG. 3 is a diagram for comparing and explaining a luminous element package according to an exemplary embodiment of the present invention with a general radiating element package in terms of radiating effect. More specifically, FIG. 3A is a diagram for explaining the radiating effect of a luminous element package according to an example of the prior art. FIG. 3B is a diagram for explaining the radiating effect of a luminous element package according to another example of the prior art. FIG. 3C is a diagram for explaining the radiating effecting of a luminous element package according to an exemplary embodiment of the present invention.

Referring to FIG. 3A, a luminous element package 11 according to an example of the prior art further includes a separate conductive plate to radiate heat generated from a luminous element to the outside. For example, the luminous element package 11 includes a luminous element 12 mounted on one surface based on a radiating substrate 13 and a radiating plate 14 bonded to another surface, which is the opposite surface to the one surface. The radiating substrate 13 has a general multi-layer printed circuit board (PCB) structure, and the radiating plate 14 is made of metal.

In the luminous element package 11 having the structure as described above, after heat (H1) generated from the luminous element 12 is moved to the radiating plate 14 via the radiating substrate 13, the radiating plate 14 radiates the heat (h1) to the outside. In this case, the luminous element package 11 does not effectively transfer the heat (H1) generated from the luminous element 12 to the radiating substrate 13 due to low heat transfer characteristics of the radiating substrate 13 having the general printed circuit board structure, thereby having low radiating efficiency. Also, considering that the luminous element package 11 must separately ensure an area provided with the radiating plate 14 outside the radiating substrate 13, the luminous element package 11 is greatly limited in the case of mounting various electronic components on both surfaces of the radiating substrate 13.

Referring to FIG. 3B, a luminous element package 21 according to another example of the prior art further includes a separate conductive plate inside a radiating substrate to radiate heat generated from a luminous element to the outside. For example, the luminous element package 21 includes a luminous element 22 and a radiating substrate 23 bonded to each other, the inside of the radiating substrate being provided with a conductive core plate 24 radiating heat (H2) generated from the luminous element 22 to the outside of the radiating substrate 23. The radiating substrate 23 has a general multi-layer printed circuit board structure, and the conductive core plate 24 is made of metal material.

The luminous element package 21 having the structure as described above radiates the heat (H2) generated from the luminous element 22 to the outside of the radiating substrate 23 via the conductive core plate 24 in the radiating substrate 23. In this case, the luminous element package 21 embeds a separate conductive core plate 24 in the radiating substrate 23, such that a complicated manufacturing process and a problem in reliability, and the like, are highly likely to occur. For example, the conductive core plate 24 is made of the metal material, such that adhesion between the conductive core plate 24 and a polymer resin of the radiating substrate 23 is very low. Accordingly, a blister phenomenon that the conductive core plate 24 and the radiating substrate 23 are easily separated occurs, thereby deteriorating reliability.

Referring to FIG. 3C, a luminous element package 100 according to another exemplary embodiment of the present invention includes a luminous element 110 and a radiating substrate 120 bonded to each other; however, may a structure in which thermal conductivity of the radiating substrate 120 itself is increased to radiate heat (H3) generated from the luminous element 110 to the outside. Accordingly, the luminous element package 100 according to the present invention does not need to include a separate metal plate, as compared to the luminous element packages 11 and 21 described with reference to FIGS. 3A and 3B, thereby making it possible to simplify a manufacturing process, reduce manufacturing cost and improve radiating effect of the luminous element 110 due to high thermal conductivity of the graphene.

As described above, the luminous substrate 120 according to the exemplary embodiment of the present invention has a multi-layer structure in which the plurality of insulating films are stacked, wherein each of the insulating films may include the polymer resin 122a and the graphene 122b distributed in the polymer resin 122a to radiate the heat generated from a heating element (for example, a luminous element) to the outside. Therefore, according to the radiating substrate and the luminous element package with the radiating substrate of the exemplary embodiment of the present invention, the radiating substrate includes the graphene having very high thermal conductivity to effectively radiate the heat generated from the heating element to the outside, thereby making it possible to improve radiating efficiency.

In addition, according to the method for manufacturing the radiating substrate 120 of the exemplary embodiment of the present invention, after forming paste with mixture of the polymer resin 122a and the graphene 122b, the insulating films formed from the paste are stacked and fired, thereby making it possible to manufacture the radiating substrate 120 in which the graphene 122b having higher thermal conductivity than metal is distributed within the polymer resin 122a. Accordingly, the method for manufacturing the radiating substrate according to the exemplary embodiment of the present invention may simplify a manufacturing process, reduce manufacturing cost, and improve radiating effect, as compared to the case of forming the separate metal plate in the radiating substrate in order to radiate the heat generated from the heating element (for example, the luminous element).

According to the radiating substrate and the luminous element package with the radiating substrate of the present invention, the radiating substrate includes the graphene having much higher thermal conductivity than the metal, thereby making it possible to considerably improve radiating efficiency as compared to the case of radiating the heat generated from the heating element using the metal plate.

According to the method for manufacturing the radiating substrate of the present invention, after forming paste with mixture of the polymer resin and the graphene, the insulating films formed by casting the paste are stacked and fired, thereby making it possible to manufacture the radiating substrate 120 in which the graphene having higher thermal conductivity than metal is distributed within the polymer resin. Accordingly, the method for manufacturing the radiating substrate according to the exemplary embodiment of the present invention may simplify a manufacturing process, reduce manufacturing cost, and improve radiating effect, as compared to the case of forming the separate metal plate in the radiating substrate in order to radiate the heat generated from the heating element (for example, the luminous element).

The present invention has been described in connection with what is presently considered to be practical exemplary embodiments. Although the exemplary embodiments of the present invention have been described, the present invention may also be used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A radiating substrate radiating heat generated from a heating element to the outside, the radiating substrate comprising:
polymer resins; and
graphenes distributed in the polymer resins to radiate the heat generated from the heating element to the outside.

2. The radiating substrate according to claim 1, wherein the graphenes having a single-layer sheet structure are interposed between the polymer resins.

3. The radiating substrate according to claim 1, further comprising a derivative formed on a surface of the graphene so as to increase reactivity between the graphene and a polar solvent.

4. The radiating substrate according to claim 1, wherein epoxy resin is used as the polymer resin.

5. The radiating substrate according to claim 1, wherein the radiating substrate has a multi-layer structure in which a plurality of insulating films are stacked.

6. A method for manufacturing a radiating substrate bonded to a heating element to radiate heat generated from the heating element to the outside, the method for manufacturing a radiating substrate comprising;
preparing a mixture by mixing polymer resins and graphenes;
forming a polymer paste by mixing and dispersing the mixture;
forming a plurality of insulating films by casting the polymer paste; and
forming a substrate laminate by stacking and firing the insulating films.

7. The method for manufacturing a radiating substrate according to claim 6, wherein the preparing the mixture includes adjusting an added amount of the graphene so that the graphene is 0.05 to 40 wt % for a total weight percent of the polymer paste.

8. The method for manufacturing a radiating substrate according to claim 6, wherein epoxy resin is used as the polymer resin.

9. The method for manufacturing a radiating substrate according to claim 6, wherein the preparing the mixture includes forming a derivative on a surface of the graphene.

10. A luminous element package, comprising:
a luminous element; and
a radiating substrate bonded to the luminous element to radiate heat generated from the luminous element;
wherein the radiating substrate includes:
polymer resins; and
graphenes distributed in the polymer resins to radiate the heat generated from the luminous element to the outside.

11. The luminous element package according to claim 10, wherein the graphenes having a single-layer sheet structure is interposed between the polymer resins.

12. The luminous element package according to claim 10, wherein the radiating substrate has a multi-layer structure in which a plurality of insulating films are stacked.
